(19) United States
(12) Patent Application Publication
(10) Pub. No.: US 2009/0152683 A1
(43) Pub. Date: Jun. 18, 2009

(54) ROUNDED DIE CONFIGURATION FOR STRESS MINIMIZATION AND ENHANCED THERMO-MECHANICAL RELIABILITY

(75) Inventors: Luu T. Nguyen, San Jose, CA (US); Vijaylaxmi Gumaste, Santa Clara, CA (US)

Correspondence Address: Beyer Law Group LLP/ NSC, P.O.Box 1687, Cupertino, CA, 95015-1687, US

(73) Assignee: NATIONAL SEMICONDUCTOR CORPORATION, Santa Clara, CA (US)

(21) Appl. No.: 11/959,422

(22) Filed: Dec. 18, 2007

(51) Int. Cl. H01L 29/06; H01L 21/304; H01L 23/495

(52) U.S. Cl. 257/620; 438/462; 257/676; 257/E29.005; 257/E21.238; 257/E23.031

(57) ABSTRACT

One aspect of the invention pertains to a semiconductor die with rounded sidewall junction edge corners. Such rounding reduces stress accumulations at those corners. In other embodiments of the invention, the sharpness of other corners and edges in the die are reduced. For example, reducing the sharpness of the bottom edge corners formed by the intersection of a sidewall and the back surface of a die can further diminish stress accumulations. One embodiment pertains to a wafer carried on a wafer support, where the wafer includes a multiplicity of such dice. Another embodiment involves a semiconductor package containing such dice. Methods of fabricating the dice are also described.

### BACKGROUND OF THE INVENTION

The present invention relates generally to integrated circuit devices (ICs). More particularly, the invention relates to improved semiconductor dice.

There are a number of conventional processes for packaging integrated circuit (IC) dice. Many packaging techniques contemplate mounting the die on a carrier such as a metallic leadframe, a substrate or a chip carrier. In many packaging arrangements, the back surface of the die is physically attached to the carrier by means of a suitable adhesive material. The die is then typically electrically connected to the leadframe leads or substrate traces and/or other package components by appropriate connectors such as bonding wires. Often, the die, the electrical connectors and portions of the leadframe/substrate are encapsulated with a molding material to protect the electrical connections and the delicate electrical components on the active side of the die.

During testing and operation, the encapsulated die and its carrier may be repeatedly exposed to temperature cycling and other environmental stresses. Such stresses may contribute to the delamination of the die from the carrier, which in turn may cause poor thermal performance, die cracking, the shearing of wirebonds and other problems. The problems are particularly acute when the carrier has a significantly different coefficient of thermal expansion than the die, such as when when the die is mounted on the die attach pad of a metallic leadframe.

Hence, there are continuing efforts to reduce stresses and to provide structures that reduce the probability of die delamination and other damage in IC packages.

### SUMMARY OF THE INVENTION

In one aspect of the invention, a semiconductor die having rounded sidewall junction edge corners is described. The rounding of such corners tends to reduce stress accumulations at those corners.

The sharpness of other corners and edges in the die may be reduced as well. For example, reducing the sharpness of bottom edge corners formed by the intersection of a sidewall and the bottom surface of a die can further diminish stress accumulations. Methods of fabricating such dice are also described.

In one method aspect of the invention, a wafer is masked with a resist to define a multiplicity of die definition islands. Each die definition island overlies an associated die and has at least one rounded corner. The wafer may then be singulated by plasma etching. Each die resulting from this process has at least one rounded sidewall junction edge corner. In some preferred embodiments, all of the sidewall junction edge corners of each die are substantially rounded.

The method may further comprise applying top and bottom resist layers to the top and bottom surfaces of the wafer. The top and bottom resist layers have a first and second set of channels. The size of the first set of channels may be different from the size of the second set of channels.

The described dice may be used in conjuction with a variety of different semiconductor packages.

In another aspect of the invention, a semiconductor package comprises a leadframe having a die attach pad, a plurality of contact leads and a die with at least one rounded sidewall junction edge corner. The die attach pad has recessed regions in the top surface of the die attach pad. The recessed regions define a plurality of pedestals supported by a web. There are gaps between adjacent pedestals. The semiconductor package further comprises a die mounted on the die attach pad, such that the die is supported by at least a plurality of the pedestals. Selected edge regions of the die are arranged to overlie recessed regions of the die attach pad. The die is electrically connected to at least some of the contact leads. The semiconductor package further comprises an adhesive that secures the die to the die attach pad. The adhesive is arranged to secure the die to the web and to the pedestals that support the die. The thickness of the adhesive between the die and the web is greater than the thickness of the adhesive between the die and the top surfaces of the pedestals that support the die. The semiconductor package further comprises an encapsulant that encapsulates the die and at least a portion of the die attach pad. The die attach pad may have rounded peripheral corners between adjacent edge surfaces of the die attach pad.

### BRIEF DESCRIPTION OF THE DRAWINGS

The invention and the advantages thereof, may best be understood by reference to the following description taken in conjunction with the accompanying drawings in which:

FIG. 1A is a diagrammatic side view of a conventional die and die attach pad.

FIG. 1B is a diagrammatic top view of contact leads and the conventional die and die attach pad illustrated in FIG. 1A.

FIG. 2A is a diagrammatic side view of an improved die according to one embodiment of the invention.

FIG. 2B is a diagrammatic top view of the improved die illustrated in FIG. 2A.

FIG. 3A is a diagrammatic side view of a wafer masked according to one embodiment of the invention.

FIG. 3B is a diagrammatic top view of the masked wafer illustrated in FIG. 3A.

FIG. 3C is a diagrammatic enlarged top view of an area in the masked wafer illustrated in FIG. 3B.

FIG. 4A is a diagrammatic side view of dice resulting from the etching and singulation of the masked wafer illustrated in FIG. 3A.

FIG. 4B is a diagrammatic top view of dice resulting from the etching and singulation of the masked wafer illustrated in FIGS. 3B-3C.

FIG. 5A is a diagrammatic side view of an integrated circuit package containing an improved die according to one embodiment of the invention.

FIG. 5B is a diagrammatic top view of some of the structures illustrated in FIG. 5A.

FIG. 6A is a diagrammatic side view of a package containing an improved die and improved die attach pad according to one embodiment of the invention.

FIG. 6B is a diagrammatic top view of some of the structures illustrated in FIG. 6A.

In the drawings, like reference numerals are sometimes used to designate like structural elements. It should also be appreciated that the depictions in the figures are diagrammatic and not to scale.

### DETAILED DESCRIPTION OF THE PREFERRED EMBODIMENTS

The present invention relates generally to the packaging of integrated circuit dice. As explained in the background section, the operation and testing of a package subjects the package to substantial stresses. These stresses may affect the performance and reliability of the package. The present invention relates to an improved integrated circuit die with characteristics that help to reduce such stresses.

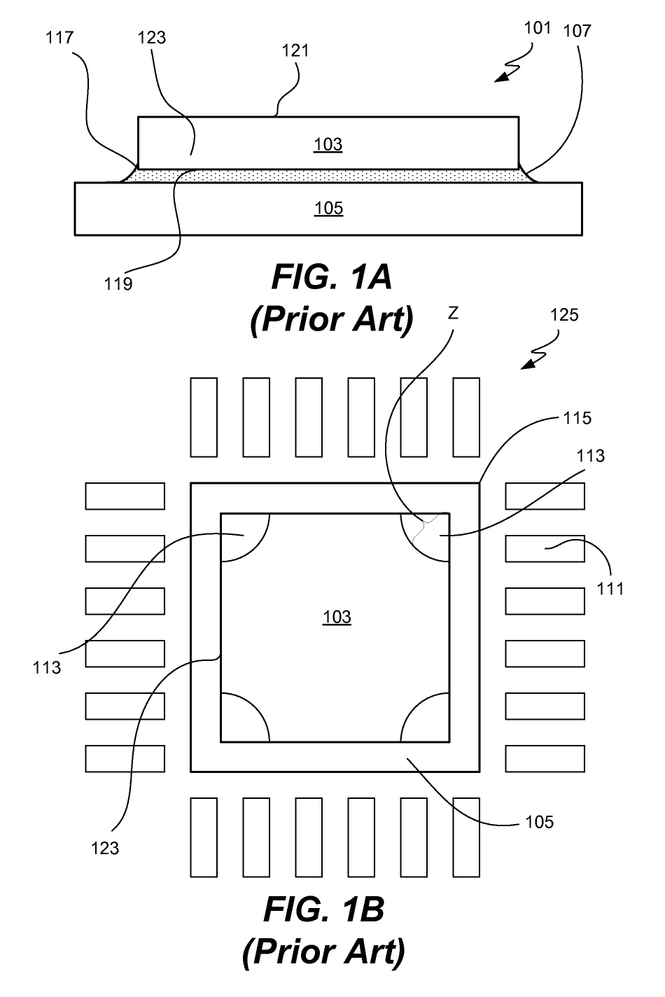

Referring initially to FIGS. 1A and 1B, a diagrammatic side view 101 and a diagrammatic top view 125 of conventional die 103 mounted on a die attach pad 105 will be described. Conventional die 103 has a top surface 121, sidewalls 123 and bottom surface 119. Contact leads 111 are also shown. Die 103 is mounted upon die attach pad 105. Adhesive 107 secures die 103 to die attach pad 105.

Conventional die 103 has a rectangular profile with substantially sharp edges and corners. Examples of such corners are corners 115 and 117 in FIGS. 1A and 1B. Sidewall junction edge corners 115 are defined by the intersection between each pair of adjacent sidewalls 123. Bottom edge corner 117 is defined by the intersection of sidewall 123 and bottom surface 119.

The sharpness of corners 115 and 117 may impair the reliability and operability of a package containing die 103. Sharp corners and edges tend to concentrate thermo-mechanical stresses. Delamination or cracking, for example, may originate from the sidewall junction edge corners 115 and propagate inward. Such delamination may cause a variety of problems, such as the shearing of bonding wires and a reduction in thermal performance.

It is generally undesirable to place active features of the die or wirebond pads in regions where stresses concentrate. Therefore, many die layouts define “exclusion regions” 113 near the sidewall junction edge corners 115 of die 103 because the corners tend to concentrate stresses. The exclusion regions 113 extend some distance from corners 115. This size of the exclusion zones (marked as distance Z in FIG. 1B) typically varies depending on a number of factors including the size of die 103. For example, the exclusion zones for some design specifications may be on the order of 200 microns for dies measuring 3.5-5 millimeters on a side to 710 microns for dies measuring 8 millimeters on a side. Within such exclusion zones, sensitive circuit elements, bus lines and bond pads are not incorporated to minimize the risk of stress-induced damage.

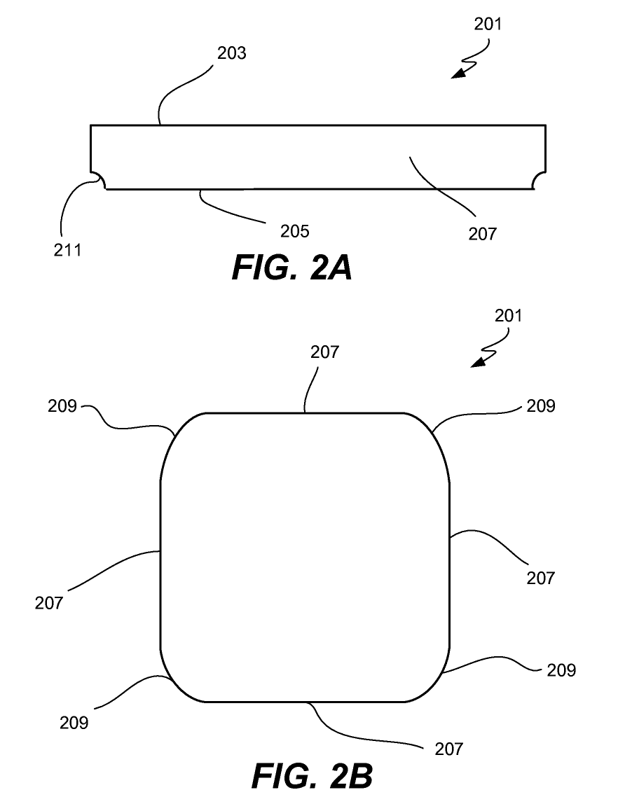

Referring next to FIGS. 2A-2B a die 201 formed in accordance with one embodiment of the invention will be described. Die 201 has a top surface 203, a bottom surface 205 and sidewalls 207. The sidewall junction edge corners 209 between adjacent sidewalls 207 are rounded significantly. The amount of curvature provided may be widely varied to meet the needs of a particular design. By way of example, sidewall junction edge corners having a radius of curvature of at least 25 microns are generally preferred, and radius of curvatures of at least 50 microns are even more preferable.

The sharpness of other corners may also be reduced. By way of example, each sidewall 207 and bottom surface 205 define a bottom edge corner 211. The bottom edge corner 211 may be rounded or at least tapered and smoothed to reduce its sharpness. In some embodiments, bottom edge corner 211 is not sharp.

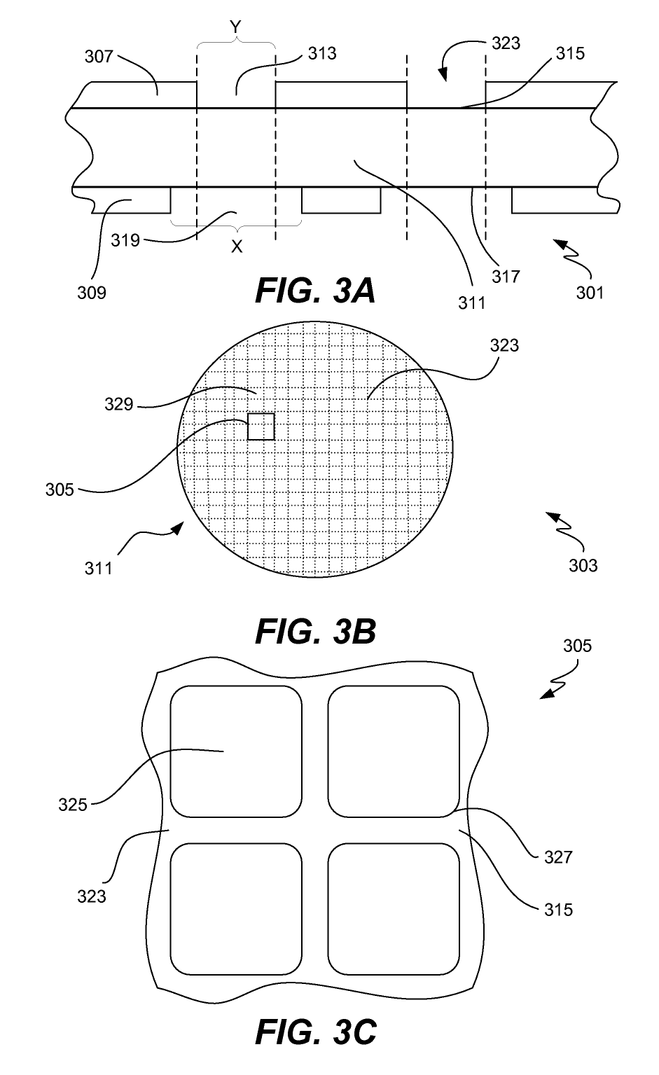

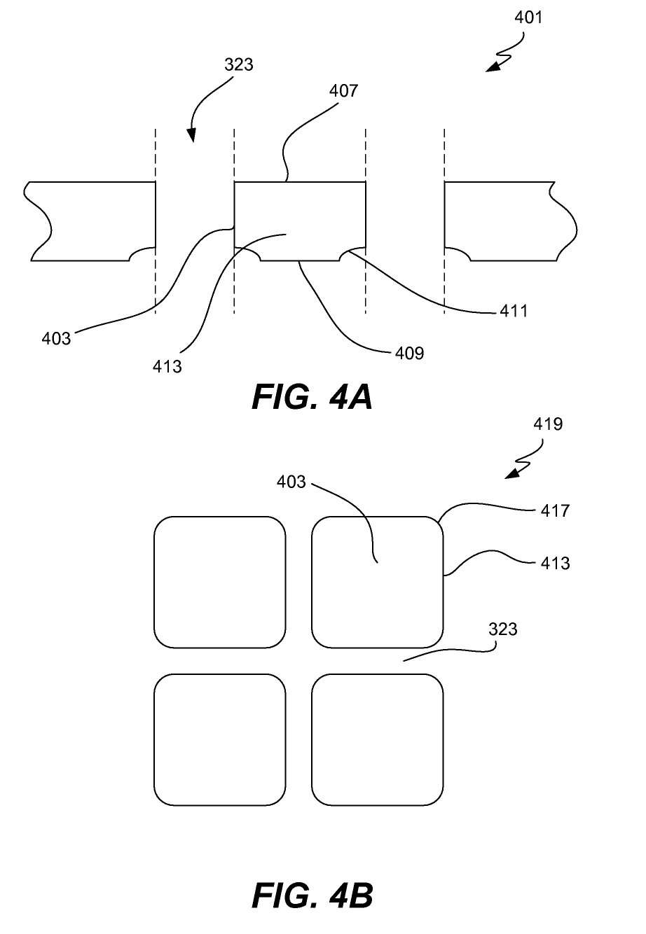

The described rounded dice can be fabricated using a variety of techniques. For example, FIGS. 3A-3C and 4A-4B illustrate an embodiment in which plasma etching is used to singulate a wafer in a manner that yields the improved dice. In other embodiments, different techniques, such as laser dicing, may be employed.

Referring now to FIGS. 3A-3C and 4A-4B, an embodiment is illustrated in which plasma etching is used to singulate the dice. The dimensions of the structures and masked regions in FIGS. 3A-3C and 4A-4B are not to scale. Some differences have been exaggerated or minimized for the sake of clarity.

FIGS. 3A-3C pertain to the masking of wafer 311 with a resist. FIG. 3A illustrates diagrammatic side view 301 of wafer 311. Wafer 311 has top surface 315 and bottom surface 317. Top surface 315 receives top resist layer 307 and bottom surface 317 receives bottom resist layer 309. The dotted lines represent projected scribe lines 323 (sometimes referred to as saw streets), which generally indicate where wafer 311 will be later cut to singulate the dice.

Top and bottom resist layers 307 and 309 focus etching on desired portions of wafer 311. Top resist layer 307 and bottom resist layers 309, which protect portions of wafer 311 from etching, define top channel 313 and bottom channel 319, respectively. Channels 313 and 319 expose portions of surfaces 315 and 317 to etching. Channels 313 and 319 are vertically aligned but do not have the same dimensions. In the illustrated embodiment, the width X of bottom channel 319 is larger than width Y of top channel 313.

The difference between widths X and Y affect the outcome of the etching process. The relative lengths of X and Y indicate that the extent of masking in the vicinity of projected saw street 323 is less on bottom surface 317 than on top surface 315. Thus, more high energy particles will enter through bottom channel 319 than top channel 313. As a result, the etching process, in addition to removing silicon from saw streets 323, will disproportionately erode the silicon on those portions of bottom surface 317 that are close to projected saw streets 323.

FIG. 3B illustrates a diagrammatic top view 303 of wafer 311. The dotted lines on top surface 315 of wafer 311 represent projected saw streets 323. Each square framed by the dotted lines represents a die 329. Top view 303 shows wafer 311 containing a multiplicity of dice 329. In the diagrammatic illustration, only a few dice 329 are shown. However, as will be appreciated by those familiar with the art, state of the art wafers tend to have on the order of hundreds, to thousands or tens of thousands of dice formed therein and it is expected that even higher device densities will be attained in future wafers.

FIG. 3C illustrates an enlarged view of area 305 of FIG. 3B. Area 305 shows die definition islands 325, separated by projected saw streets 323. Die definition islands 325 are composed of resist and cover portions of top surface 315 of wafer 311. Portions of top surface 315 that are in projected saw streets 323 lack a protective layer of resist and will be exposed during the plasma etching process. It should be appreciated that corners 327 of die definition islands 325 are rounded. This rounding of the resist corners leads to rounding of the sidewall junction edge corners of the etched dice.

Through the plasma etching of the structures in FIGS. 3A-3C, FIGS. 4A-4B are formed. It should be appreciated that other techniques, such as laser dicing or variations on masking and plasma etching, may be utilized to form structures similar to those illustrated in FIGS. 4A-4B.

FIG. 4A illustrates a diagrammatic side view of singulated dice produced from the plasma etching of wafer 311 in FIG. 3A. Wafer 311 of FIG. 3A has been cut along saw streets 323, resulting in a multiplicity of dice, including die 403. Die 403 has top surface 407, bottom surface 409 and sidewalls 413. The intersection of each sidewall 413 and bottom surface 409 define a bottom edge. The bottom edges define corners, such as bottom edge corner 411.

Bottom edge corners 411 are not sharp. By way of comparison, bottom edge corner 117 on conventional die 103 of FIG. 1A is substantially sharper. The sharpness of bottom edge corner 411 was reduced in part because of the variation in masking between the top surface 315 and bottom surface 317 of die 311 as described above and in FIG. 3A. By way of example, bottom edge corners 411 may have a radius of curvature ranging from 10 to 100 microns. Although FIG. 4A shows only non-sharp bottom edge corners 117 of bottom surface 409, the sharpness of other corners, such as the opposing corners on top surface 407, could be reduced in a similar manner.

FIG. 4B illustrates a diagrammatic top view of the results of the plasma etching process upon the structures illustrated in FIGS. 3A-3C. Saw streets 323 are largely free of silicon, resulting in singulated dice 403. Singulated dice 403 may be carried on a wafer support. Each die 403 has sidewalls 413. The intersection of each pair of sidewalls 413 defines a sidewall junction edge corner 417. It should be appreciated that the sidewall junction edge corners 417 are substantially rounded. The sidewall junction edge corners, for example, may have a radius of curvature of 50 microns, although this is not required. Sidewall junction edge corners 417 were rounded at least in part because the etching process removed much of the wafer material that was not protected by die definition islands 325 of FIG. 3C. Thus, the profile of dice 403, which has rounded sidewall junction edge corners 417, follows the profile of die definition islands 325, which also had rounded corners 327.

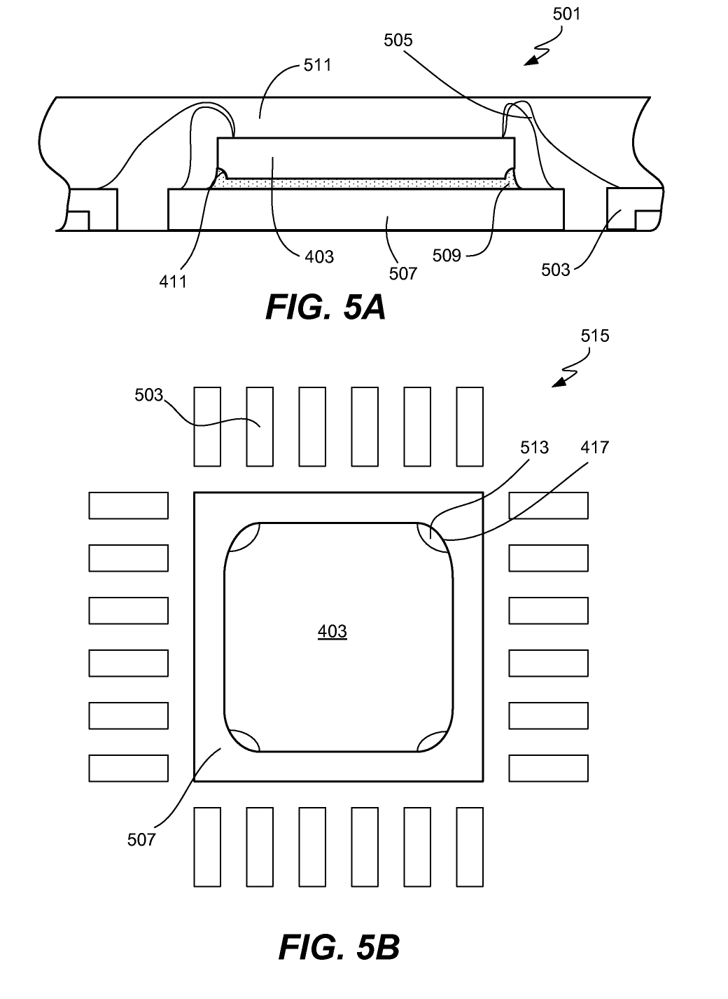

The non-sharpness of bottom edge corners such as corners 411 in FIG. 4A and sidewall junction edge corners 417 in FIG. 4B may offer substantial benefits, some of which are described in connection with FIGS. 5A and 5B. FIG. 5A illustrates a diagrammatic side view of encapsulated package 501. Encapsulated package 501 contains die 403, die attach pad 507, contact leads 503, adhesive 509, wires 505 and encapsulant 511. Die 403 has non-sharp bottom edge corners 411, whose formation was described above and in FIGS. 3A and 4A. FIG. 5B illustrates a diagrammatic top view of some of the structures of FIG. 5A. FIG. 5A includes die 403 with rounded sidewall junction edge corners 417.

As noted earlier in reference to corners 115 and 117 of conventional die 103 in FIGS. 1A and 1B, sharp edges and corners on a die tend to concentrate thermo-mechanical stresses. Such stresses, for example, may result in delamination and cracking. Reducing the sharpness of a corner, as was the case with bottom edge corner 411 in FIG. 5A and sidewall junction edge corner 417 in FIG. 5B, may reduce the buildup of stress in the corner and hence reduce the likelihood of delamination.

Moreover, the addition of bottom edge corner 411 allows more die attach adhesive 509 to collect for better fillet formation. The presence of additional adhesive provides more resistance to stresses induced by preconditioning testing or thermal cycling. Preconditioning requires exposing the packages to high humidity and temperature conditions for extended periods until moisture saturation. Subsequent board mounting at high temperatures can lead to package cracking from “popcoming” caused by the rapid escape of steam trapped inside the package. Similarly, cycling the package from low to high temperatures, e.g., −40 to +125° C., will also introduce thermo-mechanical stresses that can damage various components of the package. The enhanced die attach bond line reduces the risk of interfacial delamination and cracking.

As FIG. 5B illustrates, the reduction of stress may lead to a larger usable area on the top surface of die 403. As noted earlier, stress accumulation in the sharp corners of a die may produce exclusion regions on the die, where active features may not be placed. Exclusion region 513 of FIG. 5B, however, is smaller than exclusion region 113 of FIG. 1B. The rounded profile of sidewall junction edge corner 417 reduces stress accumulation at corner 417 of die 403, thus enabling exclusion region 513 to be relatively smaller. This may increase the amount of circuit functionality per unit area and the Gross Die Per Wafer (GDPW) yield.

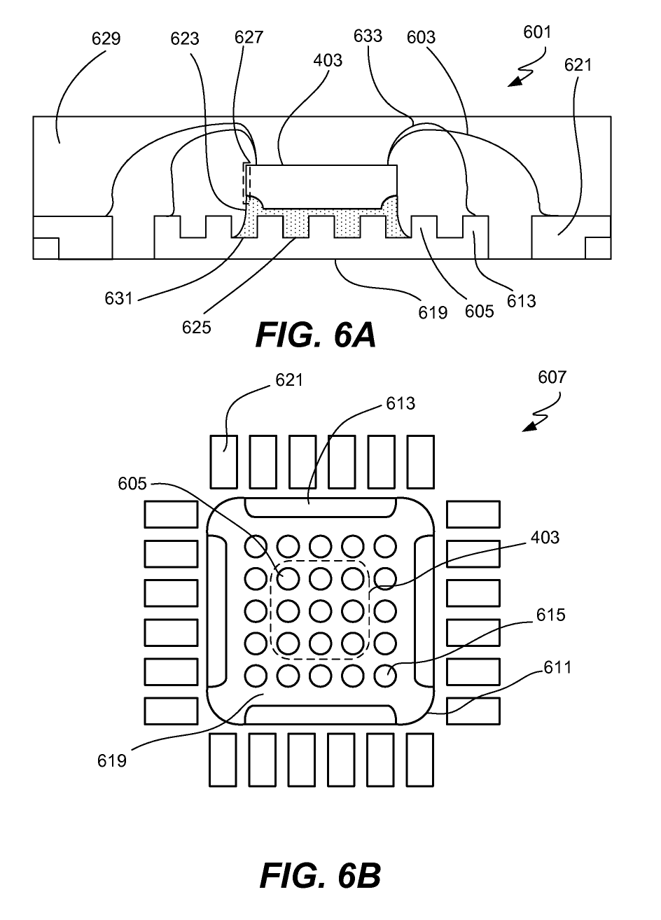

Referring next to FIGS. 6A-6B, a package incorporating improved die 403 and an improved leadframe will be described. FIG. 6A-6C include some features disclosed in application Ser. No. ______ (Attorney Docket No. NSC1P392), entitled LEADFRAME HAVING DIE ATTACH PAD WITH DELAMINATION AND CRACK-ARRESTING FEATURES, by Luu and Gumaste, filed Dec. 18, 2007, which is hereby incorporated by reference for all purposes. Both die 403 and the improved leadframe of FIGS. 6A-6B possess features that reduce the likelihood of delamination and improve the performance and reliability of the package.

FIG. 6A is a diagrammatic side view 601 of a semiconductor package including a leadframe and die 403. The leadframe includes die attach pad 619 and contact leads 621. The leadframe and die 403 are encapsulated with molding material 629. Die attach pad 619 has recessed regions 631. Recessed regions 631 define pedestals 605, which are supported by web 625. Die 403 is supported by some of the pedestals 605. Selected edge regions 627 of the die are arranged to overlie recessed region 631. Die 403 is connected electrically via wires 603 and wires 633 to contact leads 621 and bus bars 613, respectively. Adhesive 623 secures die 403 to die attach pad 619.

FIG. 6A shows how adhesive 623 connects die 403 and die attach pad 619. Adhesive 623 is arranged to secure die 403 to web 625 and to the pedestals that support die 403. The thickness of adhesive 623 between die 403 and web 625 is greater than the thickness of adhesive 623 between die 403 and top surfaces of the pedestals that support die 403. The concentration of adhesive 623 in the space between die 403 and web 625 helps to increase the strength of the bond between die 403 and die attach pad 619, thus reducing the likelihood of delamination.

FIG. 6B illustrates a diagrammatic top view 607 of die attach pad 619 and contact leads 621. The dotted line traces the rounded sidewall junction edge corners and profile of die 403. Corners 611 of die attach pad 619 are also rounded. Die attach pad 619 includes bus bars 613 and pedestals 605. Pedestals 605 have substantially circular cross sections. The lack of sharpness at corners 611 and pedestals 615 reduces stress accumulation at those locations. Some of the pedestals 615 do not underlie die 403 and surround die 403. They are in a position to arrest crack fronts propagating inward from corners 611. This feature helps prevent the crack fronts from weakening the bond between die 403 and die attach pad 619.

Although only a few embodiments of the invention have been described in detail, it should be appreciated that the invention may be implemented in many other forms without departing from the spirit or scope of the invention. Therefore, the present embodiments should be considered illustrative and not restrictive and the invention is not to be limited to the details given herein, but may be modified within the scope and equivalents of the appended claims.

What is claimed is:

1. A semiconductor device, comprising:
an integrated circuit die having a top surface, a bottom surface and a plurality of sidewalls, wherein the intersection between each pair of adjacent sidewalls defines a sidewall junction edge corner and wherein each sidewall junction edge corner is substantially rounded to reduce stress accumulations at the corners of the die.

2. The semiconductor device of claim 1, wherein the intersection between each sidewall and the bottom surface defines a bottom edge and the bottom edges do not have sharp corners.

3. The semiconductor device of claim 1 wherein the radius of curvature of each sidewall junction edge corner is at least 25 microns.

4. The semiconductor device as recited in claim 1 wherein the die is singulated from a wafer using plasma etching.

5. A singulated semiconductor wafer carried on a wafer support, the wafer comprising a multiplicity of singulated dice, each die having a top surface, a bottom surface and a plurality of sidewalls, wherein the intersection between each pair of adjacent sidewalls defines a sidewall junction edge corner and wherein each sidewall junction edge corner is substantially rounded to reduce stress accumulations at the corners of the die.

6. A method of singulating a die from a wafer, comprising:
providing a wafer having a multiplicity of dice defined therein;
masking the wafer with a resist that includes a multiplicity of die definition islands, each die definition island overlying an associated die and having at least one rounded corner; and
plasma etching the wafer to singulate the dice thereby defining a multiplicity of singulated dice, each having at least one rounded sidewall junction edge corner.

7. The method of claim 6, wherein all the sidewall junction edge corners of each die are rounded.

8. The method of claim 6, wherein the masking step further comprises:
applying a first resist layer to a top surface of the wafer;
applying a second resist layer to a bottom surface of the wafer;
forming a first set of channels in the first resist layer; and
forming a second set of channels in the second resist layer, such that the width of at least one channel in the second set of channels is substantially greater than the width of at least one channel in the first set of channels.

9. A semiconductor package comprising:
a leadframe having a die attach pad and a plurality of contact leads, the die attach pad having a top surface, a bottom surface and recessed regions in the top surface of the die attach pad that define a plurality of pedestals supported by a web, there being gaps between adjacent pedestals;
a die mounted on the die attach pad such that the die is supported by at least a plurality of the pedestals, wherein selected edge regions of the die are arranged to overlie recessed regions of the die attach pad, wherein the die is electrically connected to at least some of the contact leads, wherein the die has a top surface, a bottom surface and a plurality of sidewalls, wherein the intersection between each pair of adjacent sidewalls defines a sidewall junction edge corner and wherein each sidewall junction edge corner is substantially rounded to reduce stress accumulations at the corners of the die.
an adhesive that secures the die to the die attach pad, wherein the adhesive is arranged to secure the die to the pedestals that support the die and to the web, wherein the thickness of the adhesive between the web of the die attach pad and the die is greater than the thickness of the adhesive between the die and top surfaces of the pedestals that support the die; and
an encapsulant that encapsulates the die and at least a portion of the die attach pad.

10. The semiconductor package of claim 9, wherein the die attach pad has rounded peripheral corners between adjacent edge surfaces of the die attach pad.
